(19) United States
(12) Patent Application Publication
(10) Pub. No.: US 2025/0107331 A1
(43) Pub. Date: Mar. 27, 2025

(54) DISPLAY DEVICE

(71) Applicant: LG Display Co., Ltd., Seoul (KR)

(72) Inventors: Sungbin SHIM, Yangsan-si (KR); Dahye KWON, Seoul (KR); SangWon LEE, Paju-si (KR)

(73) Assignee: LG Display Co., Ltd., Seoul (KR)

(21) Appl. No.: 18/888,022

(22) Filed: Sep. 17, 2024

(30) Foreign Application Priority Data
Sep. 22, 2023 (KR) 10-2023-0126895

(51) Int. Cl. H10K 59/121; H10K 59/122; H10K 59/35; H10K 59/80

(52) U.S. Cl. CPC H10K 59/1213; H10K 59/122; H10K 59/35; H10K 59/80518; H10K 59/876; H10K 59/878

(57) ABSTRACT

A display device according to an example of the present specification may include a substrate having a plurality of subpixels disposed thereon, a plurality of transistors respectively disposed in the plurality of subpixels on the substrate, and a plurality of first electrodes respectively disposed on the plurality of transistors and connected to the plurality of transistors. Each first electrode includes a reflective layer and a transparent conductive layer disposed on the reflective layer. The display device may further include a plurality of light-emitting parts respectively disposed on the plurality of first electrodes, and a second electrode disposed on the light-emitting parts. The transparent conductive layer includes a first portion configured to adjoin the reflective layer and a second portion spaced apart from the reflective layer.

### CROSS-REFERENCE TO RELATED APPLICATIONS

This application claims priority to Korean Patent Application No. 10-2023-0126895 filed on Sep. 22, 2023, in the Korean Intellectual Property Office, the entire contents of which is hereby expressly incorporated by reference into the present application.

### BACKGROUND

### Field

The present disclosure relates to a display device, and more particularly, to a display device capable of improving luminous efficiency and display quality.

### Discussion of the Related Art

Unlike a liquid crystal display apparatus, an organic light-emitting display device does not require a separate light source and thus can be manufactured as a lightweight, thin display device. In addition, the organic light-emitting display device is advantageous in terms of power consumption because the organic light-emitting display device operates at a low voltage. Further, the organic light-emitting display device is studied as a next-generation display device because the organic light-emitting display device is excellent in color implementation, a response speed, a viewing angle, and a contrast ratio (CR).

The organic light-emitting display device can be referred to as a display device that autonomously emits light. The organic light-emitting display device can display images using an organic light-emitting element. The organic light-emitting element injects electrons and holes into a light-emitting layer from a cathode for injecting the electrons and an anode for injecting the holes, and emits light when excitons, which are made by coupling the injected electrons and holes, fall from an excited state to a ground state.

The organic light-emitting display devices can be classified into a top emission type display device, a bottom emission type display device, and a dual emission type display device depending on directions in which the light is emitted. The organic light-emitting display devices can be classified into a passive matrix type display device and an active matrix type display device depending on operating methods.

### SUMMARY OF THE DISCLOSURE

An object to be achieved by aspects of the present disclosure is to provide a high-efficiency, low-power display device with improved luminous efficiency.

Another object to be achieved by aspects of the present disclosure is to provide a display device capable of improving display quality by minimizing a deterioration in luminance with respect to a viewing angle and a change in color coordinates.

Objects of the present disclosure are not limited to the above-mentioned objects, and other objects, which are not mentioned above, can be clearly understood by those skilled in the art from the following descriptions.

A display device according to an embodiment of the present disclosure can include: a substrate on which a plurality of subpixels is disposed; a plurality of transistors respectively disposed in the plurality of subpixels on the substrate; a plurality of first electrodes respectively disposed on the plurality of transistors, connected to the plurality of transistors, and each including a reflective layer and a transparent conductive layer disposed on the reflective layer; a plurality of light-emitting parts respectively disposed on the plurality of first electrodes; and a second electrode disposed on the light-emitting parts, in which the transparent conductive layer includes: a first portion configured to adjoin the reflective layer; and a second portion spaced apart from the reflective layer, and in which a micro-cavity interval of light emitted from the light-emitting part, which adjoins the first portion of the transparent conductive layer, is different from a micro-cavity interval of light emitted from the light-emitting part that adjoins the second portion of the transparent conductive layer.

A display device according to another embodiment of the present disclosure can comprise: a plurality of subpixels; a plurality of transistors respectively disposed in the plurality of subpixels; a plurality of first electrodes respectively disposed on the plurality of transistors, connected to the plurality of transistors, and each comprising a reflective layer and a transparent conductive layer disposed on the reflective layer; a plurality of light-emitting parts respectively disposed on the plurality of first electrodes; and a second electrode disposed on the plurality of light-emitting parts, wherein the transparent conductive layer comprises a first portion configured to adjoin the reflective layer, and a second portion spaced apart from the reflective layer, wherein a light emitted from the light-emitting part that adjoins the first portion of the transparent conductive layer is amplified by a first micro-cavity interval, and a light emitted from the light-emitting part that adjoins the second portion of the transparent conductive layer is amplified by a second micro-cavity interval, and wherein a part of light emitted from one subpixel of the plurality of subpixels is configured to improve a light intensity at a center viewing angle, and another part of the light emitted from the one subpixel is configured to minimize a change in light intensity as a change in viewing angle.

Other detailed matters of the example embodiments of the present disclosure are included in the detailed description and the drawings.

According to the effects of the present disclosure, it is possible to improve the luminous efficiency of the display device by increasing the intensity of the light emitted from the subpixel.

According to the effects of the present disclosure, it is possible to suppress the deterioration in luminance and the change in color coordinates in accordance with the viewing angle by minimizing the change in light intensity in accordance with the change in viewing angles.

The effects according to aspects of the present disclosure are not limited to the contents discussed herein, and more various effects are included in the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a top plan view of a display device according to an embodiment of the present disclosure;

FIG. 2 is a cross-sectional view taken along line II-II′ in FIG. 1;

FIG. 3 is a graph illustrating intensities of light with respect to viewing angles in first and second portions of the display device according to the embodiment of the present disclosure;

FIG. 4A is a cross-sectional view of a display device according to another embodiment of the present disclosure;

FIG. 4B is an enlarged view of area IVb in FIG. 4A;

FIG. 5 is a cross-sectional view of a display device according to still another embodiment of the present disclosure; and

FIG. 6 is a cross-sectional view of a display device according to yet another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure.

Further, in the following description of the present disclosure, a detailed explanation of known related technologies can be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular can include plural unless expressly stated otherwise.

Components are interpreted to include an ordinary error range even if not expressly stated.

When the position relation between two parts is described using the terms such as ‘on’, ‘above’, ‘below’, ‘next’, one or more parts can be positioned between the two parts unless the terms are used with the term ‘immediately’ or ‘directly’.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Further, the term “can” fully encompasses all the meanings and coverages of the term “may.”

Hereinafter, various embodiments of the present disclosure will be described in detail with reference to accompanying drawings. All the components of each display device according to all embodiments of the present disclosure are operatively coupled and configured.

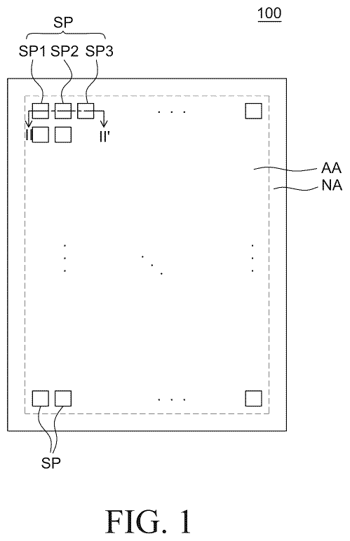

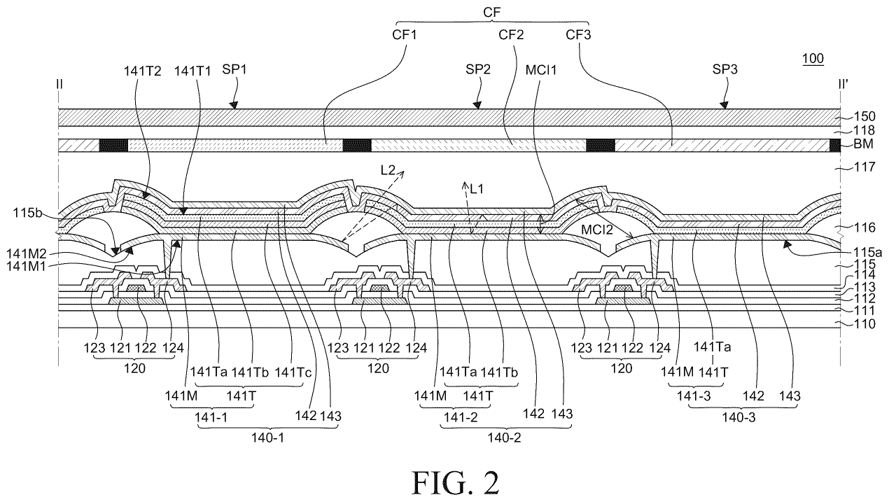

FIG. 1 is a top plan view of an organic light-emitting display device according to an embodiment of the present disclosure. FIG. 2 is a cross-sectional view taken along line II-II′ in FIG. 1.

With reference to FIGS. 1 and 2, a display device 100 includes a lower substrate 110, transistors 120, organic light-emitting elements 140, and an upper substrate 150.

With reference to FIG. 1, the lower substrate 110 is configured to support and protect several constituent elements of the display device 100. The lower substrate 110 can be made of a plastic material having flexibility. In addition, the lower substrate 110 can be made of an insulating material with transparency. For example, the lower substrate 110 can be made of transparent polyimide (PI).

The lower substrate 110 includes a display area AA (or active area) and a non-display area NA (or non-active area). The non-display area NA can surround the display area AA entirely or only in parts.

The display area AA can be disposed at a central portion of the lower substrate 110. The display area AA can be an area of the display device 100 in which images are displayed. Various display elements and various driving elements for operating the display elements can be disposed in the display area AA. For example, the display elements can be configured as the organic light-emitting elements 140 including first electrodes 141-1, 141-2, and 141-3, light-emitting parts 142, and second electrodes 143. In addition, various driving elements such as transistors, capacitors, lines, and the like, which are configured to operate the display elements, can be disposed in the display area AA.

A plurality of subpixels SP can be disposed in the display area AA. The plurality of subpixels SP can each be an area in which a plurality of gate lines disposed in a first direction and a plurality of data lines disposed in a second direction different from the first direction intersect each other. In this case, the first direction can be a horizontal direction based on FIG. 1, and the second direction can be a vertical direction based on FIG. 1. However, the present disclosure is not limited thereto. The plurality of subpixels SP can include a plurality of first subpixels SP1, a plurality of second subpixels SP2, and a plurality of third subpixels SP3 that emit light beams with different colors. For example, the plurality of first subpixels SP1 can be red subpixels, the plurality of second subpixels SP2 can be green subpixels, and the plurality of third subpixels SP3 can be blue subpixels. However, the plurality of subpixels SP can further include a fourth subpixel that is a white subpixel. However, the present disclosure is not limited thereto.

The subpixel SP is a minimum unit that constitutes a screen. The plurality of subpixels SP can each include the organic light-emitting element 140 and a driving element. The driving element can include a switching transistor, a driving transistor, and the like. The driving element can be electrically connected to signal lines such as gate lines and data lines connected to gate drivers and data drivers disposed in the non-display area NA.

The non-display area NA can be disposed in a peripheral area of the lower substrate 110. The non-display area NA can be an area in which no image is displayed. The non-display area NA can be disposed to surround the display area AA. Various constituent elements for operating the plurality of subpixels SP disposed in the display area AA can be disposed in the non-display area NA. For example, drive ICs, drive circuits, signal lines, flexible films, and the like, which are configured to supply signals for operating the plurality of subpixels SP, can be disposed. The drive IC can include a gate driver, a data driver, and the like. The drive IC and the drive circuit can be disposed by a gate-in-panel (GIP) method, a chip-on-film (COF) method, a tape automated bonding (TAB) method, a tape carrier package (TCP) method, a chip-on-glass (COG) method, and the like.

Hereinafter, the plurality of subpixels SP disposed in the display area AA of the display device 100 according to the embodiment of the present disclosure will be described in more detail with reference to FIG. 2.

With reference to FIGS. 1 and 2 together, the display device 100 according to the embodiment of the present disclosure can include the lower substrate 110, a buffer layer 111, a gate insulation layer 112, an interlayer insulation layer 113, a passivation layer 114, the transistor 120, an overcoating layer 115, the organic light-emitting element 140, a bank 116, an encapsulation layer 117, a color filter CF, a black matrix BM, a bonding member 118, and the upper substrate 150.

With reference to FIG. 2, the buffer layer 111 is disposed on the lower substrate 110. The buffer layer 111 can improve bonding forces between the lower substrate 110 and layers formed on the buffer layer 111. In addition, the buffer layer 111 can block a leak of alkaline material from the lower substrate 110 and inhibit moisture and/or oxygen penetrating from the outside of the lower substrate 110 from being diffused. The buffer layer 111 can be configured as a single layer or multilayer made of silicon nitride (SiNx) or silicon oxide (SiOx). However, the present disclosure is not limited thereto. In addition, the buffer layer 111 can be excluded depending on the type and material of the lower substrate 110, the structure and type of the transistor 120, and the like.

The transistor 120 can be disposed on the buffer layer 111 and operate the organic light-emitting element 140. The transistor 120 can be disposed in each of the plurality of subpixels SP in the display area AA. The transistor 120 disposed in each of the plurality of subpixels SP can be used as the driving element of the display device 100. For example, the transistor 120 can be a thin-film transistor (TFT), an N-channel metal oxide semiconductor (NMOS) transistor, a P-channel metal oxide semiconductor (PMOS) transistor, a complementary metal oxide semiconductor (CMOS) transistor, a field effect transistor (FET), or the like. However, the present disclosure is not limited thereto. Hereinafter, the description will be made on the assumption that the transistor 120 is the thin-film transistor. However, the present disclosure is not limited thereto.

The transistor 120 includes an active layer 121, a gate electrode 122, a source electrode 123, and a drain electrode 124. The transistor 120 illustrated in FIG. 2 is a thin-film transistor having a top-gate structure in which the gate electrode 122 is disposed on the active layer 121. However, the present disclosure is not limited thereto. The transistor 120 can be implemented as a thin-film transistor having a bottom-gate structure.

The active layer 121 of the transistor 120 is disposed on the buffer layer 111. The active layer 121 is an area in which a channel is formed when the transistor 120 operates. The active layer 121 can be made of an oxide semiconductor, amorphous silicon (a-Si), polycrystalline silicon (poly-Si), an organic semiconductor, or the like. However, the present disclosure is not limited thereto.

The gate insulation layer 112 is disposed on the active layer 121. The gate insulation layer 112 can be configured as a single layer or multilayer made of silicon nitride (SiNx) or silicon oxide (SiOx) that is an inorganic material. The gate insulation layer 112 has contact holes through which the source electrode 123 and the drain electrode 124 are in contact with a source area and a drain area of the active layer 121, respectively. As illustrated in FIG. 2, the gate insulation layer 112 can be formed over the entire surface of the lower substrate 110 or patterned to have the same width as the gate electrode 122. However, the present disclosure is not limited thereto.

The gate electrode 122 is disposed on the gate insulation layer 112. The gate electrode 122 is disposed on the gate insulation layer 112 and overlaps the channel area of the active layer 121. The gate electrode 122 can be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the gate electrode 122 can be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

The interlayer insulation layer 113 is disposed on the gate electrode 122. The interlayer insulation layer 113 can be configured as a single layer or multilayer made of silicon nitride (SiNx) or silicon oxide (SiOx) that is an inorganic material. The interlayer insulation layer 113 has contact holes through which the source electrode 123 and the drain electrode 124 are in contact with the source area and the drain area of the active layer 121, respectively.

The source electrode 123 and the drain electrode 124 are disposed on the interlayer insulation layer 113. The source electrode 123 and the drain electrode 124 are electrically connected to the active layer 121 through the contact holes of the gate insulation layer 112 and the contact holes of the interlayer insulation layer 113. The source electrode 123 and the drain electrode 124 can each be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the source electrode 123 and the drain electrode 124 can each be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

For convenience of description, FIG. 2 illustrates the driving transistor among various transistors 120 included in the display device 100. However, the other transistors such as a switching transistor can be disposed.

With reference to FIG. 2, the passivation layer 114 for protecting the transistor 120 is disposed on the transistor 120. The passivation layer 114 has a contact hole through which the drain electrode 124 of the transistor 120 is exposed. FIG. 2 illustrates that the contact hole is formed in the passivation layer 114 in order to expose the drain electrode 124. However, a contact hole can be formed to expose the source electrode 123. The passivation layer 114 can be configured as a single layer or multilayer made of silicon nitride (SiNx) or silicon oxide (SiOx). However, the passivation layer 114 can be excluded in accordance with the embodiments.

The overcoating layer 115 for planarizing an upper portion of the transistor 120 is disposed on the passivation layer 114. The overcoating layer 115 has a contact hole through which the drain electrode 124 of the transistor 120 is exposed. FIG. 2 illustrates that the contact hole is formed in the overcoating layer 115 in order to expose the drain electrode 124. However, a contact hole can be formed to expose the source electrode 123. The overcoating layer 115 can be made of one of acrylic resin, epoxy resin, phenol resin, polyamide resin, polyimide resin, unsaturated polyester resin, polyphenylene resin, polyphenylene sulfide resin, benzocyclobutene, and a photoresist. However, the present disclosure is not limited thereto.

The overcoating layer 115 can include a first top surface 115a, and a second top surface 115b inclined with respect to the first top surface 115a. The first top surface 115a is a surface of the top surface of the overcoating layer 115 that is formed as a flat surface, and the second top surface 115b is a surface of the top surface of the overcoating layer 115 that is formed as a curved surface.

Meanwhile, the second top surfaces 115b can be disposed to be inclined in different directions in areas corresponding to one subpixel SP and another adjacent subpixel SP. Therefore, a groove, which is formed as the curved surfaces of the second top surfaces 115b, which are inclined in different directions, meet together, can be disposed in the overcoating layer 115 corresponding to an area between the plurality of subpixels SP. For example, the second top surface 115b can be formed by removing a part of the overcoating layer 115. However, the present disclosure is not limited thereto.

The organic light-emitting element 140 is disposed on the overcoating layer 115. The organic light-emitting elements 140 include the first electrodes 141-1, 141-2, and 141-3 formed on the overcoating layer 115 and electrically connected to the drain electrodes 124 of the transistors 120, the light-emitting parts 142 disposed on the first electrodes 141-1, 141-2, and 141-3, and the second electrodes 143 formed on the light-emitting parts 142. In this case, the first electrodes 141-1, 141-2, and 141-3 can be anode electrodes, and the second electrode 143 can be a cathode electrode.

The first electrodes 141-1, 141-2, and 141-3 are disposed on the overcoating layer 115 and electrically connected to the drain electrodes 124 of the transistors 120 through the contact holes formed in the passivation layer 114 and the overcoating layer 115. Therefore, the organic light-emitting element 140 can be connected to the transistor 120.

FIG. 2 illustrates that the first electrodes 141-1, 141-2, and 141-3 are electrically connected to the drain electrodes 124 of the transistors 120 through the contact holes. However, the first electrodes 141-1, 141-2, and 141-3 can be electrically connected to the source electrodes 123 of the transistors 120 through contact holes in accordance with the type of transistor 120, a method of designing the drive circuit, and the like.

The first electrodes 141-1, 141-2, and 141-3 in the plurality of subpixels SP can each include a reflective layer 141M, and a transparent conductive layer 141T disposed on the reflective layer 141M.

The reflective layer 141M is disposed on the overcoating layer 115 and electrically connected to the drain electrode 124 through the contact holes formed in the passivation layer 114 and the overcoating layer 115. The reflective layer 141M is disposed to allow the light, which is emitted from the light-emitting part 142, to propagate toward the upper side of the display device 100. For example, the reflective layer 141M can be made of a reflective metallic material. However, the present disclosure is not limited thereto.

The reflective layer 141M includes a first portion 141M1 and a second portion 141M2.

The first portion 141M1 of the reflective layer 141M is disposed on the first top surface 115a of the overcoating layer 115 and disposed to adjoin the transparent conductive layer 141T. Because the first portion 141M1 of the reflective layer 141M is disposed on the first top surface 115a of the overcoating layer 115 that is formed as a flat surface, the first portion 141M1 of the reflective layer 141M can have a planar shape in accordance with a shape of the first top surface 115a.

The second portion 141M2 of the reflective layer 141M can be disposed on the second top surface 115b of the overcoating layer 115 and spaced apart from the transparent conductive layer 141T. Because the second portion 141M2 of the reflective layer 141M is disposed on the second top surface 115b including a curved surface, the second portion 141M2 of the reflective layer 141M can have a curved shape in accordance with a shape of the second top surface 115b. Therefore, the second portion 141M2 of the reflective layer 141M can be configured to reflect light toward another subpixel SP adjacent to the subpixel SP in which the corresponding reflective layer 141M is disposed.

Meanwhile, the second portion 141M2 of the reflective layer 141M can be a portion extending from the first portion 141M1 of the reflective layer 141M, which is disposed on the first top surface 115a of the overcoating layer 115, to the second top surface 115b of the overcoating layer 115. The first portion 141M1 and the second portion 141M2 of the reflective layer 141M can be integrated. However, the present disclosure is not limited thereto.

The transparent conductive layer 141T can be made of a transparent conductive material with a high work function in order to supply positive holes to the light-emitting part 142 and emit light emitted from the light-emitting part 142. For example, the first electrodes 141-1, 141-2, and 141-3 can each be made of transparent conductive oxide based on indium tin oxide (ITO), indium zinc oxide (IZO), indium tin zinc oxide (ITZO), zinc oxide (ZnO), and tin oxide (TO). However, the present disclosure is not limited thereto.

The transparent conductive layer 141T includes a first portion 141T1 and a second portion 141T2.

The first portion 141T1 of the transparent conductive layer 141T is disposed to adjoin the reflective layer 141M. The first portion 141T1 of the transparent conductive layer 141T is disposed on the first portion 141M1 of the reflective layer 141M. The first portion 141T1 of the transparent conductive layer 141T can have a planar shape in accordance with a shape of the first portion 141M1 of the reflective layer 141M.

The second portion 141T2 of the transparent conductive layer 141T is disposed to be spaced apart from the reflective layer 141M. The bank 116 is disposed between the second portion 141M2 of the reflective layer 141M and the second portion 141T2 of the transparent conductive layer 141T. Therefore, the second portion 141T2 of the transparent conductive layer 141T can be disposed to be spaced apart from the reflective layer 141M.

Meanwhile, the second portion 141T2 of the transparent conductive layer 141T can be a portion extending from the first portion 141T1 of the transparent conductive layer 141T, which is disposed on the first portion 141M1 of the reflective layer 141M, to a top surface of the bank 116. The first portion 141Tl and the second portion 141T2 of the transparent conductive layer 141T can be integrated. However, the present disclosure is not limited thereto.

With reference to FIG. 2, the second portion 141T2 of the transparent conductive layer 141T can be configured such that the light reflected from the second portion 141M2 of the reflective layer 141M of another subpixel SP adjacent to the subpixel SP, in which the corresponding transparent conductive layer 141T is disposed, reaches the second portion 141T2 of the transparent conductive layer 141T. For example, second light L2, which is emitted from the light-emitting part 142 that adjoins the second portion 141T2 of the transparent conductive layer 141T, can be reflected by the second portion 141M2 of the reflective layer 141M in another adjacent subpixel SP and reach the second portion 141T2 of the transparent conductive layer 141T, such that the second light L2 can be emitted from the subpixel SP in which the corresponding transparent conductive layer 141T is disposed.

The first electrodes 141-1, 141-2, and 141-3 of the first subpixel SP1, the second subpixel SP2, and the third subpixel

SP3 include different numbers of transparent conductive layers 141T. Therefore, the transparent conductive layers 141T included in the first electrodes 141-1, 141-2, and 141-3 can have different thicknesses in the first subpixel SP1, the second subpixel SP2, and the third subpixel SP3.

Specifically, the first electrode 141-1 of the first subpixel SP1 includes the reflective layer 141M, a second transparent conductive layer 141Tb disposed on the reflective layer 141M, a third transparent conductive layer 141Tc disposed on the second transparent conductive layer 141Tb, and a first transparent conductive layer 141Ta disposed on the third transparent conductive layer 141Tc. The first electrode 141-2 of the second subpixel SP2 includes the reflective layer 141M, the second transparent conductive layer 141Tb disposed on the reflective layer 141M, and the first transparent conductive layer 141Ta disposed on the second transparent conductive layer 141Tb. The first electrode 141-3 of the third subpixel SP3 includes the reflective layer 141M, and the first transparent conductive layer 141Ta disposed on the reflective layer 141M.

Therefore, the first electrodes 141-1, 141-2, and 141-3 can have different thicknesses in the first subpixel SP1, the second subpixel SP2, and the third subpixel SP3. For example, when the first subpixel SP1 is a red pixel, the second subpixel SP2 is a green pixel, and the third subpixel SP3 is a blue pixel, the thicknesses of the first electrodes 141-1, 141-2, and 141-3 can be configured such that the first electrode 141-1 of the first subpixel SP1 can be thicker than the first electrodes 141-2 and 141-3 of the second and third subpixels SP2 and SP3, and the first electrode 141-2 of the second subpixel SP2 can be thicker than the first electrode 141-3 of the third subpixel SP3. Therefore, the first electrodes 141-1, 141-2, and 141-3 can have micro-cavity structures in which light with a wavelength corresponding to the light emitted from the corresponding subpixel SP can be amplified in the first subpixel SP1, the second subpixel SP2, and the third subpixel SP3.

The banks 116 are disposed on the first electrodes 141-1, 141-2, and 141-3 and the overcoating layer 115. The banks 116 can define the light-emitting areas by covering edges of the first electrodes 141-1, 141-2, and 141-3 of the organic light-emitting elements 140. The bank 116 can be disposed between the adjacent subpixels SP and reduce a color mixture of the light beams emitted from the organic light-emitting elements 140 in the plurality of subpixels SP.

The bank 116 is disposed between the second portion 141T2 of the transparent conductive layer 141T and the second portion 141M2 of the reflective layer 141M that are the edges of the first electrodes 141-1, 141-2, and 141-3 between the plurality of subpixels SP.

The top surface of the bank 116 is disposed to include a curved surface. Further, the transparent conductive layer 141T disposed on the top surface of the bank 116 can be disposed to have a curved surface along the top surface of the bank 116. Therefore, the second portion 141T2 of the transparent conductive layer 141T can be configured such that the light reflected from the second portion 141M2 of the reflective layer 141M of another subpixel SP adjacent to the subpixel SP, in which the corresponding transparent conductive layer 141T is disposed, reaches the second portion 141T2 of the transparent conductive layer 141T.

The bank 116 can be made of an organic material. For example, the bank 116 can be made of polyimide resin, acrylic resin, or benzocyclobutene resin. However, the present disclosure is not limited thereto.

The light-emitting parts 142 are disposed on the banks 116 and the transparent conductive layers 141T of the first electrodes 141-1, 141-2, and 141-3. For example, the light-emitting part 142 can be a light-emitting layer that emits light with any one color among red, green, blue, and white. In addition, the light-emitting part 142 can further include various layers such as a hole transport layer, a hole injection layer, a hole blocking layer, an electron injection layer, an electron blocking layer, and an electron transport layer. However, the present disclosure is not limited thereto.

The second electrode 143 is disposed on the light-emitting part 142. The second electrode 143 can supply electrons to the light-emitting part 142. The second electrode 143 can be made of an electrically conductive material with a low work function. The second electrode 143 can be configured to allow the light, which is emitted from the light-emitting part 142, to propagate toward the upper side of the display device 100. For example, the second electrode 143 can be made of a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Meanwhile, an inorganic insulation layer for protecting the second electrode 143 can be further disposed on the second electrode 143. For example, the inorganic insulation layer can be configured as a single layer or multilayer made of silicon nitride (SiNx) or silicon oxide (SiOx). However, the present disclosure is not limited thereto.

The encapsulation layer 117 is disposed on the organic light-emitting element 140. The encapsulation layer 117 can cover the organic light-emitting element 140. The encapsulation layer 117 can protect the organic light-emitting element 140 from external moisture, oxygen, impact, and the like. The encapsulation layer 117 can be formed by alternately stacking a plurality of inorganic layers and a plurality of organic layers. For example, the inorganic layer can be made of an inorganic material such as silicon nitride (SiNx), silicon oxide (SiOx), or aluminum oxide (AlOx). The organic layer can be made of epoxy-based polymer or acrylic polymer. However, the present disclosure is not limited thereto.

The color filter CF and the black matrix BM are disposed on the encapsulation layer 117.

The color filter CF can be disposed in each of the plurality of subpixels SP. The black matrix BM can be disposed at a boundary between the plurality of subpixels SP. Therefore, the black matrix BM can separate the plurality of subpixels SP and the color filters CF disposed in the subpixels SP, thereby reducing a color mixture between the plurality of subpixels SP.

For example, in case that the light emitted from the light-emitting part 142 is white light, the color filters CF convert the light emitted from the subpixels SP into red light, green light, and blue light. For example, a first color filter CF1, which is disposed in the first subpixel SP1 that is a red subpixel, can be a red color filter. In addition, a second color filter CF2, which is a green color filter, can be disposed in the second subpixel SP2 that is a green subpixel, and a third color filter CF3, which is a blue color filter, can be disposed in the third subpixel SP3 that is a blue subpixel. However, the present disclosure is not limited thereto.

For example, the black matrix BM can be made of chromium (Cr) or other opaque metal films or made of resin. However, the present disclosure is not limited thereto.

The upper substrate 150 is disposed above the color filter CF and the black matrix BM. The upper substrate 150, together with the encapsulation layer 117, can protect the organic light-emitting element 140 from external moisture, oxygen, impact, and the like. For example, the upper substrate 150 can be made of a transparent insulating material, and the display device 100 can be configured as a top emission type display device 100. However, the present disclosure is not limited thereto.

The bonding member 118 is disposed between the color filter CF, the black matrix BM, and the upper substrate 150. The bonding member 118 can bond the color filter CF, the black matrix BM, and the upper substrate 150. The bonding member 118 can be made of a material having bondability. The bonding member 118 can be a thermosetting or naturally curable bonding agent. For example, the bonding member 118 can be an optical clear adhesive (OCA), a pressure sensitive adhesive (PSA), or the like. However, the present disclosure is not limited thereto.

In the display device 100 according to the embodiment of the present disclosure, the first electrodes 141-1, 141-2, and 141-3 in the plurality of subpixels SP, which emit light beams with different colors, can be disposed to have different thicknesses in order to improve color viewing angle properties. Therefore, the plurality of subpixels SP can each have a micro-cavity structure corresponding to light emitted from the corresponding subpixel SP. The micro-cavity structure is a structure in which the light is repeatedly reflected between the second electrodes 143 and the first electrodes 141-1, 141-2, and 141-3 spaced apart from one another by an optical path (optical length) with a particular interval, such that light with a particular wavelength is amplified by constructive interference. Therefore, the light emitted from each of the plurality of subpixels SP can be amplified, thereby improving color viewing angle properties of the display device 100.

For example, one subpixel SP can be configured to have a micro-cavity structure corresponding to the light emitted from the corresponding subpixel SP by particular intervals between the first electrodes 141-1, 141-2, and 141-3 and the second electrodes 143 of the corresponding subpixels SP. In this case, the particular intervals between the first electrodes 141-1, 141-2, and 141-3 and the second electrodes 143, which allow the subpixel SP to have the micro-cavity structure, can be defined as micro-cavity intervals, for example.

An interval between the second electrode 143 and the first portion 141M1 of the reflective layer 141M disposed in one subpixel SP can be disposed as a first micro-cavity interval MCI1 by which the light with a wavelength corresponding to the light emitted from the corresponding subpixel SP can be amplified.

Therefore, first light L1, which is light emitted from the light-emitting part 142 that adjoins the first portion 141T1 of the transparent conductive layer 141T in one subpixel SP, can be amplified by constructive interference while being repeatedly reflected between the second electrode 143 and the first portion 141M1 of the reflective layer 141M disposed in the same subpixel SP as the corresponding transparent conductive layer 141T by the first micro-cavity interval MCI1.

An interval between the second electrode 143, which is disposed in one subpixel SP, and the second portion 141M2 of the reflective layer 141M, which is disposed in another subpixel SP adjacent to the corresponding subpixel, can be disposed as a second micro-cavity interval MCI2 by which the light with a wavelength corresponding to the light emitted from the corresponding subpixel SP can be amplified.

Therefore, the second light L2, which is light emitted from the light-emitting part 142 that adjoins the second portion 141T2 of the transparent conductive layer 141T, can be amplified by constructive interference while being repeatedly reflected between the second electrode 143, which is disposed in one subpixel SP, and the second portion 141M2 of the reflective layer 141M disposed in another subpixel SP adjacent to the corresponding subpixel SP.

In the display device 100 according to the embodiment of the present disclosure, the first micro-cavity interval MCI1 can be different from the second micro-cavity interval MCI2. For example, as illustrated in FIG. 2, the first micro-cavity interval MCI1 can be smaller than the second micro-cavity interval MCI2. Therefore, the second light L2, which is amplified by the second micro-cavity interval MCI2 larger than the first micro-cavity interval MCI1, moves along the optical path with a large interval in comparison with the first light L1 amplified by the first micro-cavity interval MCI1, such that the second light L2 can have a lower light intensity than the first light L1.

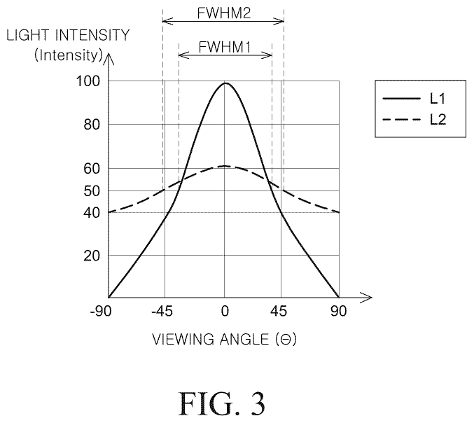

Hereinafter, the light intensities of the first light L1 and the second light L2 with respect to viewing angles of the display device 100 according to the embodiment of the present disclosure will be described in detail with reference to FIG. 3.

FIG. 3 is a graph illustrating light intensities of the first light and the second light with respect to the viewing angles of the display device according to the embodiment of the present disclosure. In the graph of FIG. 3, the X-axis indicates viewing angles θ of the first light L1 and the second light L2 when center viewing angles of the first light L1 and the second light L2 are set to 0°. The light intensities are light intensities of the first light L1 and the second light L2 with respect to the viewing angle θ on the basis that the light intensity at the center viewing angle (0°) of the first light L1 is set to 100.

With reference to FIG. 3, the light intensity at the center viewing angle (0°) of the first light L1, which is the light emitted from the light-emitting part 142 that adjoins the first portion 141T1 of the transparent conductive layer 141T, is 100. Therefore, the highest light intensity is implemented at the center viewing angle (0°) of the first light L1.

Further, it can be seen that the light intensity of the first light L1 decreases as the viewing angle θ changes from the center viewing angle (0°), such that the light intensity at a viewing angle of −90° and 90° of the first light L1 decreases to 0.

The second light L2, which is the light emitted from the light-emitting part 142 that adjoins the second portion 141T2 of the transparent conductive layer 141T, has a light intensity of 60 at the center viewing angle (0°). Therefore, it can be seen that the second light L2 has a lower light intensity at the center viewing angle (0°) than the first light L1. For example, the intensity at the center viewing angle (0°) of the first light L1 can be higher than the intensity at the center viewing angle (0°) of the second light L2.

Further, the light intensity of the second light L2 decreases as the viewing angle θ changes from the center viewing angle (0°), and the light intensity at the viewing angle of −90° and 90° of the second light L2 decreases to 40.

Meanwhile, in the graph illustrating a distribution of particular wavelengths, a width of the distribution corresponding to ½ of the maximum value can be referred to as a full width at half maximum (FWHM). In this regard, with reference to FIG. 3, it can be seen that a full width at half maximum FWHM1 of the first light L1, which is a width of the distribution corresponding to ½ of a maximum intensity of the first light L1, is smaller than a full width at half maximum FWHM2 of the second light L2 that is a width of the distribution corresponding to ½ of a maximum intensity of the second light L2. Specifically, in the distribution in which the light intensity corresponding to ½ of the maximum intensity of the first light L1 and the second light L2 is 50, the full width at half maximum FWHM1 of the first light L1 can be smaller than the full width at half maximum FWHM2 of the second light L2.

Meanwhile, it can be seen that the second light L2 has a smaller change in light intensity with respect to the change in viewing angles than the first light L1 because a value of the change in light intensity of the first light L1 is 100 and a value of the change in light intensity of the second light L2 is 20 as the viewing angle changes from the center viewing angle (0°) to the viewing angle of −90° and 90°.

The display device having the micro-cavity structure has a structure in which the light is amplified by constructive interference by being repeatedly reflected between the first electrode and the second electrode set to have the micro-cavity interval. However, the light can have high straightness as the intensity increases. Therefore, when the straightness increases as the intensity of the light increases, the viewing angle at which the light can be detected can be narrowed. Therefore, because the light is amplified in the display device having the micro-cavity structure, the light with high intensity is emitted, such that the viewing angle at which the light emitted from the display device can be detected can be narrowed. For example, the light intensity of the light emitted from the display device can decrease as the viewing angle changes from the center viewing angle. Therefore, there can occur a problem in that the luminance of the emitted light deteriorates and the color coordinate changes as the viewing angle changes from the center viewing angle of the light emitted from the display device. In addition, there can also occur a problem in that the display quality of the display device deteriorates because of the changes in luminance and color coordinates caused by the change in viewing angle.

Therefore, in the display device 100 according to the embodiment of the present disclosure, a part of the light emitted from one subpixel SP is configured to improve the light intensity at the center viewing angle (0°), and another part of the light emitted from one subpixel SP is configured to minimize the change in light intensity in accordance with the change in the viewing angle θ, such that the luminous efficiency of the display device 100 can be improved, and the deterioration in luminance and the change in color coordinate in accordance with the viewing angle can be minimized.

Specifically, in the display device 100 according to the embodiment of the present disclosure, the first light L1, which is the light emitted from the light-emitting part 142 that adjoins the first portion 141T1 of the transparent conductive layer 141T, is amplified by the first micro-cavity interval MCI1 that is the interval between the second electrode 143 and the first portion 141M1 of the reflective layer 141M disposed in the corresponding subpixel SP. Further, the second light L2, which is the light emitted from the light-emitting part 142 that adjoins the second portion 141T2 of the transparent conductive layer 141T, is amplified by the second micro-cavity interval MCI2 that is the interval between the second electrode 143 and the second portion 141M2 of the reflective layer 141M disposed in another subpixel SP adjacent to the corresponding subpixel. In this case, the second light L2, which is amplified by the second micro-cavity interval MCI2 larger than the first micro-cavity interval MCI1, moves along the optical path with a large interval in comparison with the first light L1 amplified by the first micro-cavity interval MCI1, such that the second light L2 can have a lower light intensity than the first light L1. Therefore, the first light L1, which has a relatively high light intensity, improves the light straightness, thereby improving the light intensity at the center viewing angle (0°). Further, the second light L2, which has a relatively low light intensity, can have reduced straightness, such that the second light L2 can be detected even at a relatively wide viewing angle, and the change in light intensity in accordance with the change in the viewing angle θ can be minimized. As such, the light intensity of the first light L1 emitted from the subpixel SP can be increased, such that the luminous efficiency of the display device 100 can be improved, and the second light L2 can be configured to compensate for the change in light intensity in accordance with the change in viewing angle of the first light L1, such that the deterioration in luminance and the change in color coordinates in accordance with the viewing angle can be minimized. Therefore, in the display device 100 according to the embodiment of the present disclosure, a part of the light emitted from one subpixel SP is configured to improve the light intensity at the center viewing angle (0°), and another part of the light emitted from one subpixel SP is configured to minimize the change in light intensity in accordance with the change in the viewing angle θ. Thus, the luminous efficiency of the display device 100 can be improved, and the deterioration in luminance and the change in color coordinates in accordance with the viewing angle can be minimized, which can improve the display quality of the display device 100 and provide the high-efficiency, low-power display device 100.

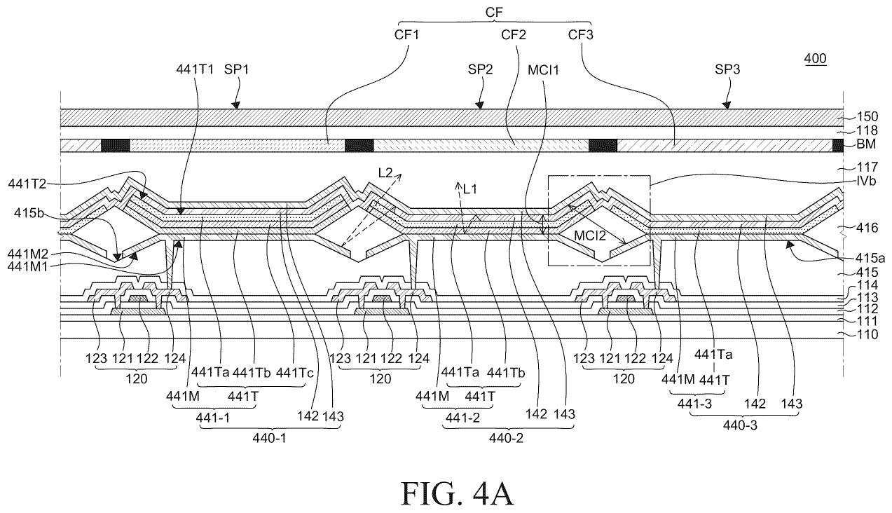

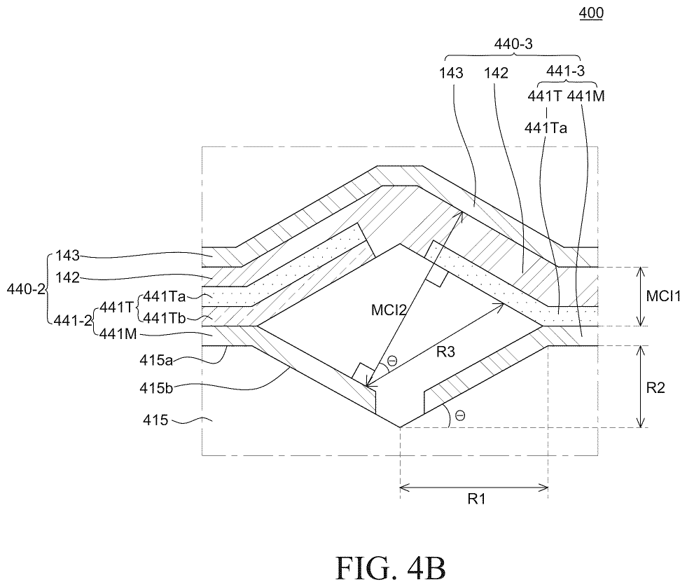

Hereinafter, a display device according to another embodiment of the present disclosure will be described in detail with reference to FIGS. 4A and 4B.

FIG. 4A is a cross-sectional view of a display device according to another embodiment of the present disclosure. FIG. 4B is an enlarged view of area IVb in FIG. 4A. A display device 400 in FIGS. 4A and 4B is substantially identical in configuration to the display device 100 in FIGS. 1 to 3, except for an overcoating layer 415, first electrodes 441-1, 441-2, and 441-3, and the bank 116. Therefore, repeated descriptions of the identical components will be omitted or may be briefly provided.

First, with reference to FIG. 4A, the overcoating layer 415 can include a first top surface 415a and a second top surface 415b inclined with respect to the first top surface 415a. In this case, the first top surface 415a is a surface formed as a flat surface of a top surface of the overcoating layer 415, and the second top surface 415b is a surface including a flat surface inclined with respect to the first top surface 415a.

Meanwhile, the second top surfaces 415b can be disposed to be inclined in different directions in areas corresponding to one subpixel SP and another adjacent subpixel SP. Therefore, a groove, which is formed as the flat surfaces of the second top surfaces 415b, which are inclined in different directions, meet together, can be disposed in the overcoating layer 415 corresponding to an area between the plurality of subpixels SP.

The first electrodes 441-1, 441-2, and 441-3 are disposed on the overcoating layer 415. The first electrodes 441-1, 441-2, and 441-3 can each include a reflective layer 441M disposed on the overcoating layer 415, and a transparent conductive layer 441T disposed on the reflective layer 441M.

The reflective layer 441M includes a first portion 441M1 disposed on the first top surface 415a of the overcoating layer 415, and a second portion 441M2 disposed on the second top surface 415b of the overcoating layer 415. Because the first portion 441M1 of the reflective layer 441M is disposed on the first top surface 415a of the overcoating layer 415, such that the first portion 441M1 of the reflective layer 441M can have a planar shape in accordance with a shape of the first top surface 415a. Because the second portion 441M2 of the reflective layer 441M is disposed on the second top surface 415b that is the flat surface inclined with respect to the first top surface 415a, the second portion 441M2 of the reflective layer 441M can have a planar shape inclined with respect to the first top surface 415a along the second top surface 415b. Therefore, the second portion 441M2 of the reflective layer 441M can be configured to reflect light toward another subpixel SP adjacent to the subpixel SP in which the corresponding reflective layer 441M is disposed.

The transparent conductive layer 441T includes the first portion 441T1 and the second portion 441T2. The first portion 441T1 of the transparent conductive layer 441T is disposed on the first portion 441M1 of the reflective layer 441M. The first portion 441T1 of the transparent conductive layer 441T can have a planar shape in accordance with a shape of the first portion 441M1 of the reflective layer 441M. The second portion 441T2 of the transparent conductive layer 441T can be disposed to be spaced apart from the reflective layer 441M. With reference to FIG. 4A, a second portion 441T2 of the transparent conductive layer 441T, which is disposed in one subpixel SP among the plurality of subpixels SP, can be disposed to be parallel to the second portion 441M2 of the reflective layer 441M disposed in another adjacent subpixel SP.

A bank 416 is disposed between the second portion 441M2 of the reflective layer 441M and the second portion 441T2 of the transparent conductive layer 441T. With reference to FIG. 4A, a top surface of the bank 416 can be disposed to include a flat surface inclined with respect to the first top surface 415a of the overcoating layer 415. Therefore, the second portion 441T2 of the transparent conductive layer 441T disposed on the inclined top surface of the bank 416 can be disposed to be parallel to the second portion 441M2 of the reflective layer 441M disposed in another subpixel SP adjacent to the corresponding subpixel SP.

The top surface of the bank 416 can include a flat surface inclined with respect to the first top surface 415a of the overcoating layer 415 and be disposed in a tapered shape. For example, the bank 416 can be made of an inorganic material with a shape that is easy to control. However, the present disclosure is not limited thereto.

In this case, an inclination of the second top surface 415b of the overcoating layer 415 and an inclination of the top surface of the bank 416 can be 30° to 45°. However, the present disclosure is not limited thereto. For example, in case that the inclination of the second top surface of the overcoating layer and the inclination of the top surface of the bank exceed 45°, a thickness of the light-emitting part disposed above the bank and made of an organic material can be a non-uniform thickness because of the top surface of the bank with a large inclination. Further, in case that the inclination of the second top surface of the overcoating layer and the inclination of the top surface of the bank are less than 30°, it is difficult for the second portion of the reflective layer to reflect the light toward another subpixel adjacent to the subpixel in which the corresponding reflective layer is disposed. Therefore, the inclination of the second top surface 415b of the overcoating layer 415 and the inclination of the top surface of the bank 416 are set to 30° to 45°, such that the thickness of the light-emitting part 142 disposed above the bank 416 can be uniform, and the second portion 441M2 of the reflective layer 441M can be configured to reflect the light toward another adjacent subpixel SP. However, the present disclosure is not limited thereto.

An interval between the second electrode 143 and the first portion 441M1 of the reflective layer 441M disposed in one subpixel SP can be disposed as a first micro-cavity interval MCI1 by which the light with a wavelength corresponding to the light emitted from the corresponding subpixel SP can be amplified.

Therefore, first light L1, which is light emitted from the light-emitting part 142 that adjoins the first portion 441T1 of the transparent conductive layer 441T in one subpixel SP, can be amplified by constructive interference while being repeatedly reflected between the second electrode 143 and the first portion 441M1 of the reflective layer 441M disposed in the same subpixel SP as the corresponding transparent conductive layer 441T by the first micro-cavity interval MCI1.

An interval between the second electrode 143, which is disposed in one subpixel SP, and the second portion 441M2 of the reflective layer 441M, which is disposed in another subpixel SP adjacent to the corresponding subpixel, can be disposed as a second micro-cavity interval MCI2 by which the light with a wavelength corresponding to the light emitted from the corresponding subpixel SP can be amplified.

Therefore, the second light L2, which is light emitted from the light-emitting part 142 that adjoins the second portion 441T2 of the transparent conductive layer 441T, can be amplified by constructive interference while being repeatedly reflected between the second electrode 143, which is disposed in one subpixel SP, and the second portion 441M2 of the reflective layer 441M disposed in another subpixel SP adjacent to the corresponding subpixel SP.

Hereinafter, an example method of setting the second micro-cavity interval MCI2 will be described in detail with reference to FIG. 4B together according to aspects of the present disclosure.

In FIG. 4B, R1 indicates a width of an area in which the second top surface 415b of the overcoating layer 415 corresponding to any one subpixel SP is disposed between the plurality of subpixels SP, R2 indicates a height of an area in which the second top surface 415b is disposed, R3 indicates a width of the second top surface 415b, and θ indicates an inclination of the second top surface 415b.

With reference to FIG. 4B, the inclination θ of the second top surface 415b and the width R3 of the second top surface 415b can be set by means of the width R1 of the area, in which the second top surface 415b is disposed, and the height R2 of the area in which the second top surface 415b is disposed. For example, in case that the inclination θ of the second top surface 415b is intended to be set to 30° and the width R3 of the second top surface 415b is intended to be 1408 nm, the width R1 of the area, in which the second top surface 415b is disposed, can be calculated as 1219 nm that is a value of 1408 nm×cos 30°, and the height R2 of the area, in which the second top surface 415b is disposed, can be calculated as 704 nm that is a value of 1408 nm×sin 30°. Therefore, the inclination θ of the second top surface 415b can be set to 30° and the width R3 of the second top surface 415b can be set to 1408 nm by a method of removing a part of the top surface of the overcoating layer 415 to set a width of 1219 nm and a height of 704 nm.

Further, the second micro-cavity interval MCI2 can be set by means of the inclination θ of the second top surface 415b and the width R3 of the second top surface 415b. For example, in order to set the second micro-cavity interval MCI2 to 1792 nm in the display device in which the thickness of the transparent conductive layer 441T is 84 nm, the thickness of the light-emitting part 142 is 300 nm, and the inclination θ of the second top surface 415b is 30°, the width R3 of the second top surface 415b is set by reducing the thickness of the transparent conductive layer 441T and the thickness of the light-emitting part 142 from the second micro-cavity interval MCI2, in which case the width R3 of the second top surface 415b can be calculated as a value of (1792 nm−84 nm−300 nm)×sec30°, i.e. 1626 nm.

In the display device 400 according to another embodiment of the present disclosure, a part of the light emitted from one subpixel SP is configured to improve the light intensity at the center viewing angle (0°), and another part of the light emitted from one subpixel SP is configured to minimize the change in light intensity in accordance with the change in the viewing angle θ, such that the luminous efficiency of the display device 400 can be improved, and the deterioration in luminance and the change in color coordinate in accordance with the viewing angle can be minimized.

Specifically, in the display device 400 according to another embodiment of the present disclosure, the first light L1, which is the light emitted from the light-emitting part 142 that adjoins the first portion 441T1 of the transparent conductive layer 441T, is amplified by the first micro-cavity interval MCI1 that is the interval between the second electrode 143 and the first portion 441M1 of the reflective layer 441M disposed in the corresponding subpixel SP. Further, the second light L2, which is the light emitted from the light-emitting part 142 that adjoins the second portion 441T2 of the transparent conductive layer 441T, is amplified by the second micro-cavity interval MCI2 that is the interval between the second electrode 143 and the second portion 441M2 of the reflective layer 441M disposed in another subpixel SP adjacent to the corresponding subpixel. In this case, the second light L2, which is amplified by the second micro-cavity interval MCI2 larger than the first micro-cavity interval MCI1, moves along the optical path with a large interval in comparison with the first light L1 amplified by the first micro-cavity interval MCI1, such that the second light L2 can have a lower light intensity than the first light L1. Therefore, the first light L1, which has a relatively high light intensity, improves the light straightness, thereby improving the light intensity at the center viewing angle (0°). Further, the second light L2, which has a relatively low light intensity, can have reduced straightness, such that the second light L2 can be detected even at a relatively wide viewing angle, and the change in light intensity in accordance with the change in the viewing angle θ can be minimized. As such, the light intensity of the first light L1 emitted from the subpixel SP can be increased, such that the luminous efficiency of the display device 400 can be improved, and the second light L2 can be configured to compensate for the change in light intensity in accordance with the change in viewing angle of the first light L1, such that the deterioration in luminance and the change in color coordinates in accordance with the viewing angle can be minimized. Therefore, in the display device 400 according to another embodiment of the present disclosure, a part of the light emitted from one subpixel SP is configured to improve the light intensity at the center viewing angle (0°), and another part of the light emitted from one subpixel SP is configured to minimize the change in light intensity in accordance with the change in the viewing angle θ. Accordingly, the luminous efficiency of the display device 400 can be improved, and the deterioration in luminance and the change in color coordinates in accordance with the viewing angle can be minimized, which can improve the display quality of the display device 400 and provide the high-efficiency, low-power display device 400.

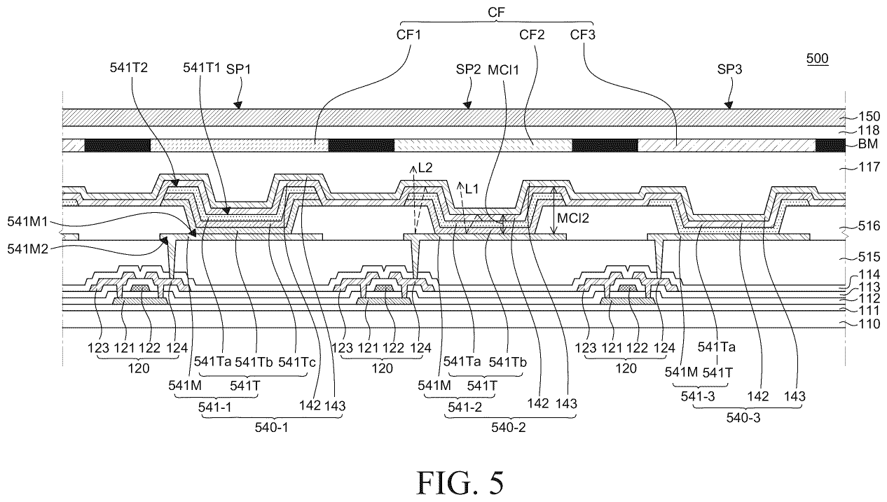

Hereinafter, a display device according to still another embodiment of the present disclosure will be described in detail with reference to FIG. 5.

FIG. 5 is a cross-sectional view of a display device according to still another embodiment of the present disclosure. A display device 500 in FIG. 5 is substantially identical in configuration to the display device 100 in FIGS. 1 to 3, except for an overcoating layer 515, first electrodes 541-1, 541-2, and 541-3, and the bank 516. Therefore, repeated descriptions of the identical components will be omitted or may be briefly provided.

With reference to FIG. 5, the overcoating layer 515 having a flat top surface is disposed between the plurality of transistors 120 and the plurality of first electrodes 541-1, 541-2, and 541-3. Therefore, all the bottom surfaces of the plurality of first electrodes 541-1, 541-2, and 541-3 can be disposed on the same plane on the top surface of the overcoating layer 515.

The first electrodes 541-1, 541-2, and 541-3 can each include a reflective layer 541M disposed on the overcoating layer 515, and a transparent conductive layer 541T disposed on the reflective layer 541M.

With reference to FIG. 5, the reflective layer 541M includes a first portion 541M1 configured to adjoin the transparent conductive layer 541T, and a second portion 541M2 spaced apart from the transparent conductive layer 541T. The transparent conductive layer 541T includes a first portion 541T1 configured to adjoin the reflective layer 541M, and a second portion 541T2 spaced apart from the reflective layer 541M. For example, the first portion 541M1 of the reflective layer 541M can adjoin the first portion 541T1 of the transparent conductive layer 541T, and the second portion 541M2 of the reflective layer 541M can be spaced apart from the transparent conductive layer 541T.

A bank 516 is disposed between the second portion 541M2 of the reflective layer 541M and the second portion 541T2 of the transparent conductive layer 541T. Therefore, the second portion 541M2 of the reflective layer 541M and the second portion 541T2 of the transparent conductive layer 541T can be disposed to be spaced apart from each other at a predetermined interval.

Meanwhile, the bank 516 can be configured to define the second micro-cavity interval MCI2 together with the second portion 541T2 of the transparent conductive layer 541T and the light-emitting part 142. In this case, a refractive index of the bank 516 can be 1.8 or more. For example, in case that refractive indexes of materials, which constitute the transparent conductive layer 541T and the light-emitting part 142 disposed above the bank 516, are 1.7 to 1.8, the bank 516 can be made of a material with a refractive index of 1.8 or more. However, the present disclosure is not limited thereto.

An interval between the second electrode 143 and the first portion 541M1 of the reflective layer 541M disposed in one subpixel SP can be disposed as a first micro-cavity interval MCI1 by which the light with a wavelength corresponding to the light emitted from the corresponding subpixel SP can be amplified.

Therefore, first light L1, which is light emitted from the light-emitting part 142 that adjoins the first portion 541T1 of the transparent conductive layer 541T in one subpixel SP, can be amplified by constructive interference while being repeatedly reflected between the second electrode 143 and the first portion 541M1 of the reflective layer 541M disposed in the same subpixel SP as the corresponding transparent conductive layer 541T by the first micro-cavity interval MCI1.

An interval between the second electrode 143 and the second portion 541M2 of the reflective layer 541M disposed in one subpixel SP can be disposed as a second micro-cavity interval MCI2 by which the light with a wavelength corresponding to the light emitted from the corresponding subpixel SP can be amplified.

Therefore, second light L2, which is light emitted from the light-emitting part 142 that adjoins the second portion 541T2 of the transparent conductive layer 541T, can be amplified by constructive interference while being repeatedly reflected between the second electrode 143 and the second portion 541M2 of the reflective layer 541M disposed in one subpixel SP.

In the display device 500 according to still another embodiment of the present disclosure, a part of the light emitted from one subpixel SP is configured to improve the light intensity at the center viewing angle (0°), and another part of the light emitted from one subpixel SP is configured to minimize the change in light intensity in accordance with the change in the viewing angle θ, such that the luminous efficiency of the display device 500 can be improved, and the deterioration in luminance and the change in color coordinate in accordance with the viewing angle can be minimized.

Specifically, in the display device 500 according to still another embodiment of the present disclosure, the first light L1, which is the light emitted from the light-emitting part 142 that adjoins the first portion 541T1 of the transparent conductive layer 541T, is amplified by the first micro-cavity interval MCI1 that is the interval between the second electrode 143 and the first portion 541M1 of the reflective layer 541M disposed in the corresponding subpixel SP. Further, the second light L2, which is the light emitted from the light-emitting part 142 that adjoins the second portion 541T2 of the transparent conductive layer 541T, is amplified by the second micro-cavity interval MCI2 that is the interval between the second electrode 143 and the second portion 541M2 of the reflective layer 541M disposed in one subpixel SP.

In this case, the second light L2, which is amplified by the second micro-cavity interval MCI2 larger than the first micro-cavity interval MCI1, moves along the optical path with a large interval in comparison with the first light L1 amplified by the first micro-cavity interval MCI1, such that the second light L2 can have a lower light intensity than the first light L1. Therefore, the first light L1, which has a relatively high light intensity, improves the light straightness, thereby improving the light intensity at the center viewing angle (0°). Further, the second light L2, which has a relatively low light intensity, can have reduced straightness, such that the second light L2 can be detected even at a relatively wide viewing angle, and the change in light intensity in accordance with the change in the viewing angle θ can be minimized. As such, the light intensity of the first light L1 emitted from the subpixel SP can be increased, such that the luminous efficiency of the display device 500 can be improved, and the second light L2 can be configured to compensate for the change in light intensity in accordance with the change in viewing angle of the first light L1, such that the deterioration in luminance and the change in color coordinates in accordance with the viewing angle can be minimized. Thus, in the display device 500 according to still another embodiment of the present disclosure, a part of the light emitted from one subpixel SP is configured to improve the light intensity at the center viewing angle (0°), and another part of the light emitted from one subpixel SP is configured to minimize the change in light intensity in accordance with the change in the viewing angle θ. Accordingly, the luminous efficiency of the display device 500 can be improved, and the deterioration in luminance and the change in color coordinates in accordance with the viewing angle can be minimized, which can improve the display quality of the display device 500 and provide the high-efficiency, low-power display device 500.

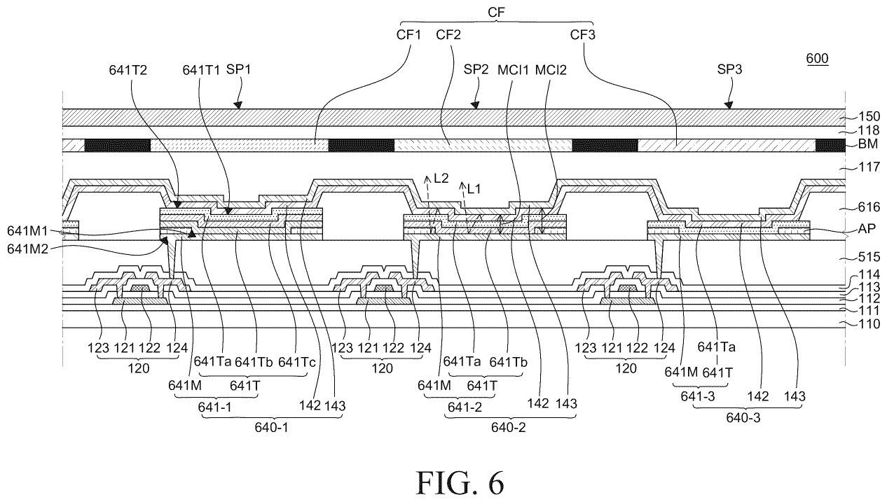

Hereinafter, a display device according to yet another embodiment of the present disclosure will be described in detail with reference to FIG. 6.

FIG. 6 is a cross-sectional view of a display device according to yet another embodiment of the present disclosure. A display device 600 in FIG. 6 is substantially identical in configuration to the display device 500 in FIG. 5, except for first electrodes 641-1, 641-2, and 641-3, an additional pattern AP, and a bank 616. Therefore, repeated descriptions of the identical components will be omitted or may be briefly provided.

With reference to FIG. 6, the first electrodes 641-1, 641-2, and 641-3 can each include a reflective layer 641M disposed on the overcoating layer 515, and a transparent conductive layer 641T disposed on the reflective layer 641M.

The reflective layer 641M includes a first portion 641M1 configured to adjoin the transparent conductive layer 641T, and a second portion 641M2 spaced apart from the transparent conductive layer 641T. The transparent conductive layer 641T includes a first portion 641T1 configured to adjoin the reflective layer 641M, and a second portion 641T2 spaced apart from the reflective layer 641M. For example, the first portion 641Ml of the reflective layer 641M can adjoin the first portion 641T1 of the transparent conductive layer 641T, and the second portion 641M2 of the reflective layer 641M can be spaced apart from the transparent conductive layer 641T.

The additional pattern AP is disposed between the second portion 641M2 of the reflective layer 641M and the second portion 641T2 of the transparent conductive layer 641T. The additional pattern AP can be configured to define the second micro-cavity interval MCI2 together with the second portion 641T2 of the transparent conductive layer 641T and the light-emitting part 142. Therefore, the second portion 641M2 of the reflective layer 641M and the second portion 641T2 of the transparent conductive layer 641T can be disposed to be spaced apart from each other at a predetermined interval.

Meanwhile, the additional pattern AP can be made of the same material as the transparent conductive layer 641T. Therefore, because the additional pattern AP has the same refractive index as the transparent conductive layer 641T, it is possible to minimize a degree to which the second micro-cavity interval MCI2 is distorted by a difference in refractive index between the additional pattern AP and the transparent conductive layer 641T. In this case, for example, because the transparent conductive layer 641T can be formed after the additional pattern AP is disposed, an interface can be present between the additional pattern AP and the transparent conductive layer 641T. However, the present disclosure is not limited thereto.

The bank 616 can be disposed between a part of the second portion 641T2 of the transparent conductive layer 641T and the light-emitting part 142. Further, the bank 616 can be disposed to surround side surfaces of the first electrodes 641-1, 641-2, and 641-3 and a side surface of the additional pattern AP.

An interval between the second electrode 143 and the first portion 641Ml of the reflective layer 641M disposed in one subpixel SP can be disposed as a first micro-cavity interval MCI1 by which the light with a wavelength corresponding to the light emitted from the corresponding subpixel SP can be amplified.

Therefore, first light L1, which is light emitted from the light-emitting part 142 that adjoins the first portion 641T1 of the transparent conductive layer 641T in one subpixel SP, can be amplified by constructive interference while being repeatedly reflected between the second electrode 143 and the first portion 641M1 of the reflective layer 641M disposed in the same subpixel SP as the corresponding transparent conductive layer 641T by the first micro-cavity interval MCI1.

An interval between the second electrode 143 and the second portion 641M2 of the reflective layer 641M disposed in one subpixel SP can be disposed as a second micro-cavity interval MCI2 by which the light with a wavelength corresponding to the light emitted from the corresponding subpixel SP can be amplified.

Therefore, second light L2, which is light emitted from the light-emitting part 142 that adjoins the second portion 641T2 of the transparent conductive layer 641T, can be amplified by constructive interference while being repeatedly reflected between the second electrode 143 and the second portion 641M2 of the reflective layer 641M disposed in one subpixel SP.

In the display device 600 according to still another embodiment of the present disclosure, a part of the light emitted from one subpixel SP is configured to improve the light intensity at the center viewing angle (0°), and another part of the light emitted from one subpixel SP is configured to minimize the change in light intensity in accordance with the change in the viewing angle θ, such that the luminous efficiency of the display device 600 can be improved, and the deterioration in luminance and the change in color coordinate in accordance with the viewing angle can be minimized.

Specifically, in the display device 600 according to still another embodiment of the present disclosure, the first light L1, which is the light emitted from the light-emitting part 142 that adjoins the first portion 641T1 of the transparent conductive layer 641T, is amplified by the first micro-cavity interval MCI1 that is the interval between the second electrode 143 and the first portion 641M1 of the reflective layer 641M disposed in the corresponding subpixel SP. Further, the second light L2, which is the light emitted from the light-emitting part 142 that adjoins the second portion 641T2 of the transparent conductive layer 641T, is amplified by the second micro-cavity interval MCI2 that is the interval between the second electrode 143 and the second portion 641M2 of the reflective layer 641M disposed in one subpixel SP.

In this case, the second light L2, which is amplified by the second micro-cavity interval MCI2 larger than the first micro-cavity interval MCI1, moves along the optical path with a large interval in comparison with the first light L1 amplified by the first micro-cavity interval MCI1, such that the second light L2 can have a lower light intensity than the first light L1. Therefore, the first light L1, which has a relatively high light intensity, improves the light straightness, thereby improving the light intensity at the center viewing angle (0°). Further, the second light L2, which has a relatively low light intensity, can have reduced straightness, such that the second light L2 can be detected even at a relatively wide viewing angle, and the change in light intensity in accordance with the change in the viewing angle θ can be minimized. As such, the light intensity of the first light L1 emitted from the subpixel SP can be increased, such that the luminous efficiency of the display device 600 can be improved, and the second light L2 can be configured to compensate for the change in light intensity in accordance with the change in viewing angle of the first light L1, such that the deterioration in luminance and the change in color coordinates in accordance with the viewing angle can be minimized. Therefore, in the display device 600 according to yet another embodiment of the present disclosure, a part of the light emitted from one subpixel SP is configured to improve the light intensity at the center viewing angle (0°), and another part of the light emitted from one subpixel SP is configured to minimize the change in light intensity in accordance with the change in the viewing angle θ. Accordingly, the luminous efficiency of the display device 600 can be improved, and the deterioration in luminance and the change in color coordinates in accordance with the viewing angle can be minimized, which can improve the display quality of the display device 600 and provide the high-efficiency, low-power display device 600.

The example embodiments of the present disclosure can also be described as follows:

According to an aspect of the present disclosure, a display device can include: a substrate on which a plurality of subpixels is disposed; a plurality of transistors respectively disposed in the plurality of subpixels on the substrate; a plurality of first electrodes respectively disposed on the plurality of transistors, connected to the plurality of transistors, and each including a reflective layer and a transparent conductive layer disposed on the reflective layer; a plurality of light-emitting parts respectively disposed on the plurality of first electrodes; and a second electrode disposed on the light-emitting parts, in which the transparent conductive layer includes: a first portion configured to adjoin the reflective layer; and a second portion spaced apart from the reflective layer, and in which a micro-cavity interval of light emitted from the light-emitting part, which adjoins the first portion of the transparent conductive layer, is different from a micro-cavity interval of light emitted from the light-emitting part that adjoins the second portion of the transparent conductive layer.

The micro-cavity interval of the light emitted from the light-emitting part, which adjoins the first portion of the transparent conductive layer, can be smaller than the micro-cavity interval of the light emitted from the light-emitting part that adjoins the second portion of the transparent conductive layer.

An intensity at a center viewing angle of the light emitted from the light-emitting part, which adjoins the first portion of the transparent conductive layer, can be higher than an intensity at a center viewing angle of the light emitted from the light-emitting part that adjoins the second portion of the transparent conductive layer.

A full width at half maximum of the light emitted from the light-emitting part, which adjoins the first portion of the transparent conductive layer, can be smaller than a full width at half maximum of the light emitted from the light-emitting part that adjoins the second portion of the transparent conductive layer.

The display device can further comprise an overcoating layer disposed between the plurality of transistors and the plurality of first electrodes and including a first top surface and a second top surface inclined with respect to the first top surface.

The reflective layer can comprise a first portion configured to adjoin the first portion of the transparent conductive layer and disposed on the first top surface, and a second portion spaced apart from the transparent conductive layer and disposed on the second top surface.

A micro-cavity interval of light emitted from the light-emitting part, which adjoins the first portion of the transparent conductive layer disposed in one subpixel among the plurality of subpixels, can be an interval between the second electrode and the first portion of the reflective layer disposed in one subpixel.

A micro-cavity interval of light emitted from the light-emitting part, which adjoins the second portion of the transparent conductive layer disposed in one subpixel, can be an interval between the second electrode disposed in one subpixel and the second portion of the reflective layer disposed in another subpixel adjacent to one subpixel.

The display device can further comprise a bank disposed between the second portion of the reflective layer and the second portion of the transparent conductive layer between the plurality of subpixels.

The second top surface of the overcoating layer and a top surface of the bank can include curved surfaces.

The display device can further comprise a bank disposed between the second portion of the reflective layer and the second portion of the transparent conductive layer between the plurality of subpixels.

The second top surface of the overcoating layer and a top surface of the bank can include flat surfaces inclined with respect to the first top surface of the overcoating layer.

The second portion of the transparent conductive layer, which is disposed in one subpixel among the plurality of subpixels, can be parallel to the second portion of the reflective layer disposed in another adjacent subpixel.

The display device can further comprise an overcoating layer disposed between the plurality of transistors and the plurality of first electrodes and having a flat top surface.

The reflective layer can be disposed on a top surface of the overcoating layer.

The reflective layer can comprise a first portion configured to adjoin the first portion of the transparent conductive layer and a second portion spaced apart from the transparent conductive layer.

A micro-cavity interval of light emitted from the light-emitting part, which adjoins the first portion of the transparent conductive layer disposed in one subpixel among the plurality of subpixels, can be an interval between the second electrode and the first portion of the reflective layer disposed in one subpixel.

A micro-cavity interval of light emitted from the light-emitting part, which adjoins the second portion of the transparent conductive layer disposed in one subpixel, can be an interval between the second electrode and the second portion of the reflective layer disposed in one subpixel.

The display device can further comprise a bank disposed between the second portion of the reflective layer and the second portion of the transparent conductive layer between the plurality of subpixels.

A refractive index of the bank can be 1.8 or more.

The display device can further comprise an additional pattern disposed between the second portion of the transparent conductive layer and the second portion of the reflective layer and a bank disposed to surround a side surface of the first electrode and a side surface of the additional pattern.

The additional pattern can be made of the same material as the transparent conductive layer.

The plurality of subpixels can comprise a first subpixel, a second subpixel, and a third subpixel that emit light beams with different colors.

The transparent conductive layers in the first subpixel, the second subpixel, and the third subpixel can have different thicknesses.

According to an aspect of the present disclosure, a display device can comprise: a plurality of subpixels; a plurality of transistors respectively disposed in the plurality of subpixels; a plurality of first electrodes respectively disposed on the plurality of transistors, connected to the plurality of transistors, and each comprising a reflective layer and a transparent conductive layer disposed on the reflective layer; a plurality of light-emitting parts respectively disposed on the plurality of first electrodes; and a second electrode disposed on the plurality of light-emitting parts, wherein the transparent conductive layer comprises a first portion configured to adjoin the reflective layer, and a second portion spaced apart from the reflective layer, wherein a light emitted from the light-emitting part that adjoins the first portion of the transparent conductive layer is amplified by a first micro-cavity interval, and a light emitted from the light-emitting part that adjoins the second portion of the transparent conductive layer is amplified by a second micro-cavity interval, and wherein a part of light emitted from one subpixel of the plurality of subpixels is configured to improve a light intensity at a center viewing angle, and another part of the light emitted from the one subpixel is configured to minimize a change in light intensity as a change in viewing angle.

The display device further comprises an overcoating layer disposed between the plurality of transistors and the plurality of first electrodes and including a first top surface and a second top surface inclined with respect to the first top surface, wherein the reflective layer comprises: a first portion configured to adjoin the first portion of the transparent conductive layer and disposed on the first top surface; and a second portion spaced apart from the transparent conductive layer and disposed on the second top surface.

The first micro-cavity interval is an interval between the second electrode and the first portion of the reflective layer disposed in the one subpixel, and the second micro-cavity interval is an interval between the second electrode disposed in the one subpixel and the second portion of the reflective layer disposed in another subpixel adjacent to the one subpixel.

The display device further comprises an overcoating layer disposed between the plurality of transistors and the plurality of first electrodes and having a flat top surface, wherein the reflective layer is disposed on a top surface of the overcoating layer, and wherein the reflective layer comprises: a first portion configured to adjoin the first portion of the transparent conductive layer; and a second portion spaced apart from the transparent conductive layer.

The first micro-cavity interval is an interval between the second electrode and the first portion of the reflective layer disposed in the one subpixel, and the second micro-cavity interval is an interval between the second electrode and the second portion of the reflective layer disposed in the one subpixel.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate including a plurality of subpixels disposed thereon;
a plurality of transistors respectively disposed in the plurality of subpixels on the substrate;
a plurality of first electrodes respectively disposed on the plurality of transistors, and connected to the plurality of transistors, each of the plurality of first electrodes comprising a reflective layer and a transparent conductive layer disposed on the reflective layer;
a plurality of light-emitting parts respectively disposed on the plurality of first electrodes; and
a second electrode disposed on the plurality of light-emitting parts,
wherein the transparent conductive layer comprises:
a first portion configured to adjoin the reflective layer; and
a second portion spaced apart from the reflective layer, and
wherein a micro-cavity interval of light emitted from the light-emitting part, which adjoins the first portion of the transparent conductive layer, is different from a micro-cavity interval of light emitted from the light-emitting part that adjoins the second portion of the transparent conductive layer.

2. The display device of claim 1, wherein the micro-cavity interval of the light emitted from the light-emitting part, which adjoins the first portion of the transparent conductive layer, is smaller than the micro-cavity interval of the light emitted from the light-emitting part that adjoins the second portion of the transparent conductive layer.

3. The display device of claim 1, wherein an intensity at a center viewing angle of the light emitted from the light-emitting part, which adjoins the first portion of the transparent conductive layer, is higher than an intensity at a center viewing angle of the light emitted from the light-emitting part that adjoins the second portion of the transparent conductive layer.

4. The display device of claim 1, wherein a full width at half maximum of the light emitted from the light-emitting part, which adjoins the first portion of the transparent conductive layer, is smaller than a full width at half maximum of the light emitted from the light-emitting part that adjoins the second portion of the transparent conductive layer.

5. The display device of claim 1, further comprising:
an overcoating layer disposed between the plurality of transistors and the plurality of first electrodes, and including a first top surface and a second top surface inclined with respect to the first top surface,
wherein the reflective layer comprises:
a first portion configured to adjoin the first portion of the transparent conductive layer and disposed on the first top surface of the overcoating layer; and
a second portion spaced apart from the transparent conductive layer and disposed on the second top surface of the overcoating layer.

6. The display device of claim 5, wherein a micro-cavity interval of light emitted from the light-emitting part, which adjoins the first portion of the transparent conductive layer disposed in one subpixel among the plurality of subpixels, is an interval between the second electrode and the first portion of the reflective layer disposed in the one subpixel, and
wherein a micro-cavity interval of light emitted from the light-emitting part, which adjoins the second portion of the transparent conductive layer disposed in the one subpixel, is an interval between the second electrode disposed in the one subpixel and the second portion of the reflective layer disposed in another subpixel adjacent to the one subpixel.

7. The display device of claim 5, further comprising:
a bank disposed between the second portion of the reflective layer and the second portion of the transparent conductive layer between the plurality of subpixels,
wherein the second top surface of the overcoating layer and a top surface of the bank include curved surfaces.

8. The display device of claim 5, further comprising:
a bank disposed between the second portion of the reflective layer and the second portion of the transparent conductive layer between the plurality of subpixels,
wherein the second top surface of the overcoating layer and a top surface of the bank include flat surfaces inclined with respect to the first top surface of the overcoating layer.

9. The display device of claim 8, wherein the second portion of the transparent conductive layer, which is disposed in one subpixel among the plurality of subpixels, is parallel to the second portion of the reflective layer disposed in another subpixel adjacent to the one subpixel.

10. The display device of claim 1, further comprising:
an overcoating layer disposed between the plurality of transistors and the plurality of first electrodes, and having a top surface,
wherein the reflective layer is disposed on the top surface of the overcoating layer, and
wherein the reflective layer comprises:
a first portion configured to adjoin the first portion of the transparent conductive layer; and
a second portion spaced apart from the transparent conductive layer.

11. The display device of claim 10, wherein a micro-cavity interval of light emitted from the light-emitting part, which adjoins the first portion of the transparent conductive layer disposed in one subpixel among the plurality of subpixels, is an interval between the second electrode and the first portion of the reflective layer disposed in the one subpixel, and
wherein a micro-cavity interval of light emitted from the light-emitting part, which adjoins the second portion of the transparent conductive layer disposed in the one subpixel, is an interval between the second electrode and the second portion of the reflective layer disposed in the one subpixel.

12. The display device of claim 10, further comprising:
a bank disposed between the second portion of the reflective layer and the second portion of the transparent conductive layer between the plurality of subpixels.

13. The display device of claim 12, wherein a refractive index of the bank is about 1.8 or more.

14. The display device of claim 10, further comprising:
an additional pattern disposed between the second portion of the transparent conductive layer and the second portion of the reflective layer; and
a bank disposed to surround a side surface of the first electrode and a side surface of the additional pattern.

15. The display device of claim 14, wherein the additional pattern is made of a same material as the transparent conductive layer.

16. The display device of claim 1, wherein the plurality of subpixels comprise a first subpixel, a second subpixel, and a third subpixel all configured to emit light beams with different colors, and
wherein the transparent conductive layers in the first subpixel, the second subpixel, and the third subpixel have different thicknesses.

17. A display device comprising:
a plurality of subpixels;
a plurality of transistors respectively disposed in the plurality of subpixels;
a plurality of first electrodes respectively disposed on the plurality of transistors, and connected to the plurality of transistors, each of the plurality of first electrodes comprising a reflective layer and a transparent conductive layer disposed on the reflective layer;
a plurality of light-emitting parts respectively disposed on the plurality of first electrodes; and
a second electrode disposed on the plurality of light-emitting parts,
wherein the transparent conductive layer comprises a first portion configured to adjoin the reflective layer, and a second portion spaced apart from the reflective layer,
wherein a light emitted from the light-emitting part that adjoins the first portion of the transparent conductive layer is amplified by a first micro-cavity interval, and a light emitted from the light-emitting part that adjoins the second portion of the transparent conductive layer is amplified by a second micro-cavity interval, and
wherein a part of light emitted from one subpixel of the plurality of subpixels is configured to improve a light intensity at a center viewing angle, and another part of the light emitted from the one subpixel is configured to minimize a change in light intensity as a change in viewing angle.

18. The display device of claim 17, further comprising:
an overcoating layer disposed between the plurality of transistors and the plurality of first electrodes, and including a first top surface and a second top surface inclined with respect to the first top surface,
wherein the reflective layer comprises:
a first portion configured to adjoin the first portion of the transparent conductive layer and disposed on the first top surface of the overcoating layer; and
a second portion spaced apart from the transparent conductive layer and disposed on the second top surface of the overcoating layer.

19. The display device of claim 18, wherein the first micro-cavity interval is an interval between the second electrode and the first portion of the reflective layer disposed in the one subpixel, and
wherein the second micro-cavity interval is an interval between the second electrode disposed in the one subpixel and the second portion of the reflective layer disposed in another subpixel adjacent to the one subpixel.

20. The display device of claim 17, further comprising:
an overcoating layer disposed between the plurality of transistors and the plurality of first electrodes, and having a top surface,
wherein the reflective layer is disposed on the top surface of the overcoating layer, and
wherein the reflective layer comprises:
a first portion configured to adjoin the first portion of the transparent conductive layer; and
a second portion spaced apart from the transparent conductive layer.

21. The display device of claim 20, wherein the first micro-cavity interval is an interval between the second electrode and the first portion of the reflective layer disposed in the one subpixel, and
wherein the second micro-cavity interval is an interval between the second electrode and the second portion of the reflective layer disposed in the one subpixel.
